(19) United States
(12) Patent Application Publication
(10) Pub. No.: US 2024/0302470 A1
(43) Pub. Date: Sep. 12, 2024

(54) Reducing Eddy Current Influences in MR Imaging

(71) Applicant: Siemens Healthineers AG, Forchheim (DE)

(72) Inventors: Manuela Rösler, Erlangen (DE); David Grodzki, Erlangen (DE)

(73) Assignee: Siemens Healthineers AG, Forchheim (DE)

(21) Appl. No.: 18/597,986

(22) Filed: Mar. 7, 2024

(30) Foreign Application Priority Data
Mar. 10, 2023 (DE) 10 2023 202 188.9

(51) Int. Cl. G01R 33/565; G01R 33/48; G01R 33/54

(52) U.S. Cl. CPC G01R 33/56518; G01R 33/482; G01R 33/543

(57) ABSTRACT

An MR sequence with a repetition in which a constant portion of the gradient strength adjoins a ramp portion. In the constant portion, an HF (high frequency) pulse is carried out. At the beginning of the constant portion, a specifiable decay duration is waited until the excitation pulse is carried out. During the decay duration, eddy current effects decay away.

### TECHNICAL FIELD

The present disclosure relates to a method for operating an imaging modality of a magnetic resonance system by obtaining image signals in a large number of repetitions of an MR sequence (magnetic resonance sequence). In at least one of the repetitions, in a ramp portion, a strength of a gradient field is altered, in a constant portion following the ramp portion, the strength of the gradient field is kept constant, and in the constant portion an HF pulse (excitation pulse) is carried out. The present disclosure further relates to a corresponding magnetic resonance system.

### BACKGROUND

In nuclear spin tomography, strong high-frequency fields are used to excite the spins in the body of a patient. Fields in the region of up to 40 pT at frequencies of up to 300 MHz or more are generated by pulse amplifiers with several 10 kW transmitting power.

High-end systems in MRT (magnetic resonance tomography) are equipped with ever stronger gradient fields, which are intended to enable new (research) applications. Such applications are, above all, in the field of diffusion-weighted imaging. In [Froidevaux et al., High-resolution short-T2 MRI using a high-performance gradient. Magn Reson Med. 2020 October; 84(4):1933-1946, https://onlinelibrary.wiley.com/doi/epdf/10.1002/mrm.28254], the advantages of the PETRA and/or ZTE sequence with gradient strengths of 200 mT/m are demonstrated, which show significant improvements as compared with weaker gradient strengths and other sequences for imaging substances with short T2*. This is based, above all, on the fact that the readout time with extremely strong gradients can be kept advantageously short, and thus, the T2* decay can be kept low during the readout process. Thereby, higher resolutions and the acquisition of substances with still shorter T2* become possible.

The PETRA sequences (Pointwise Encoding Time Reduction with Radial Acquisition) are described extensively in the dissertation by David M. Grodzki, “Entwicklung von neuen Sequenzen mit ultrakurzen Echozeiten für die klinische Magnetresonanzbildgebung” [Development of New Sequences with Ultra-short Echo Times for Clinical Magnetic Resonance Imaging], Würzburg, December 2011.

Changes in the magnetic field can produce eddy currents in conductive structures. This is also the case, in particular, in metal structures of an MRT apparatus. Thus, for example, eddy currents can arise at the flanks of gradient switching operations. According to Lenz's law, eddy currents generate magnetic fields that counteract the cause, in this case, the gradient. Thereby, distortions of the local gradient field and, consequently, faulty image encodings arise, which ultimately make themselves apparent as image artifacts. It is especially to be expected that eddy currents, most particularly those with short time constants in the millisecond or microsecond range in which strong gradient amplitudes play a decisive role even in the PETRA sequence and can present a major challenge.

It is further to be expected that these and other influences in other sequences with ultrashort echo times, such as the UTE (Ultra Short Echo Time) sequence, will become even stronger since in this sequence, during the readout procedure, “ramping” takes place (the running-up and running-down of the gradients is also known as “ramping”). For this reason, consideration is given here most particularly to the PETRA sequence.

Established approaches to preventing eddy current effects also consist in avoiding, as far as possible, metal components in an MRT apparatus and/or providing suitable magnetic field screening.

### SUMMARY

It is, therefore, an object of the present disclosure to propose a method for operating an MRT imaging modality with which artifacts caused by eddy currents are prevented.

Therefore, according to the present disclosure, a method is provided for operating an imaging modality of a magnetic resonance system by obtaining image signals in a large number of repetitions of an MR sequence. In MRT imaging, the two-dimensional or three-dimensional k-space is sampled. Typically, for each excitation, one or more lines through the k-space are read out. The interplay of transmitting (TX) and receiving (RX) and the gradient progressions in the spatial directions are summarized under the name “sequence.” An MRT sequence represents an electromagnetic pulse sequence that is produced by an MRT device in order to generate slice images. An electromagnetic pulse sequence of this type corresponds to a set of particular radio frequency and gradient pulses, which are repeated multiple times during a sampling procedure for different k-space regions. In short time intervals between the excitation pulses, signals are received and are automatically evaluated by means of a computer and images are calculated. A repetition, therefore, comprises substantially at least one gradient ramp, at least one excitation pulse, and at least one readout procedure.

Specifically, in a ramp portion of the (possibly each) repetition, a strength of at least one gradient field is altered. In particular, in the ramp portion, the magnetic field gradient is brought to the desired target amplitude.

In a constant portion adjoining the ramp portion, the strength of the gradient field is kept constant. Thus, as soon as the strength and/or the target amplitude of the gradient field and/or the magnetic field gradient is achieved, it is typically kept constant until the end of a repetition.

In the constant portion, an HF pulse is carried out. Thus, while the gradient field remains constant, an excitation pulse, that is, an HF pulse, is applied. The HF pulse can thus be introduced in a largely static magnetic field.

Following the HF pulse, a readout procedure can take place. The readout procedure has a duration, for example, until the end of the respective repetition. The readout procedure of a repetition serves, for example, for sampling a line in the k-space. At the end of the readout procedure, typically, a new repetition begins.

At the beginning of the constant portion, according to the disclosure, a specifiable decay time is waited until the HF pulse is carried out. The beginning of the constant portion represents the end of the ramp portion. During the ramp portion, the strength of the gradient field changes so that in conductive structures of the MRT system, eddy currents arise as a result of induced voltages. These eddy currents decay when the strength of the gradient field no longer changes. The decay of the eddy currents, therefore, begins with the start of the constant portion immediately following the ramp portion. Since the eddy currents are known to evoke artifacts in the imaging modality, it is advantageous to allow the eddy currents to decay sufficiently. The HF pulse is, therefore, not triggered immediately after the ramp portion, but rather a specified and/or specifiable decay duration is waited after the end of the ramp portion until the HF pulse is triggered. This means that the decay duration does not represent the shortest duration, as determined by the system, between the ramp end and the HF pulse and, in particular, is not 0. Rather, an actual waiting time is introduced for the decay during which the system “waits” or is inactive before the triggering of the HF pulse. By way of this waiting, the eddy currents generated can decay so that the artifacts in the imaging are reduced or prevented.

In one exemplary aspect, it is provided that the decay duration is determined automatically by an algorithm on the basis of parameters of the imaging modality. In particular, by way of the algorithm, a calibration can be carried out as to how long the decay duration is to be set for the given system. A parameter of the imaging modality can be, for example, the extent of a specific eddy current effect and/or the degree of an artifact. As soon as this level of artifact falls, for example, below a predetermined threshold, the corresponding time point can be defined as the end of the decay duration. In the algorithm, however, other parameters can also be taken into account, relating, for example, to the type of the present MRT system and/or its hardware. In such a calibration, as soon as a shortest possible decay duration has been found, it can be used in subsequent MRT sequences.

In a special aspect, the decay duration is in a range from 1 μs to 5 ms, in particular in a range from 10 μs to 2 ms. For example, the decay duration or decay time is defined as a time period during which the amplitude falls to the factor 1/e. Typical repetition times are approximately 1 to 2 ms. The attempt should, therefore, firstly be made to keep the decay duration as long as possible so that a noticeable decay of the eddy currents within the repetition duration is at all possible.

In a further exemplary aspect, it is provided that the constant portion of the repetition is formed temporally longer than the ramp portion. Specifically, if the readout procedure lasts a relatively long time, it is necessary that sufficient time is available within a repetition window for the readout procedure. In this case, it is favorable if the ramp portion is short and steep. Otherwise, if the readout procedure is only short, the majority of the repetition duration can be used for the ramp portion so that the acquisition can be quieter overall.

In a further exemplary aspect, it can be provided that the strength of the gradient field, i.e., the gradient strength, is at least partially above 10 mT/m, in particular above 20 mT/m. In modern MRT systems, gradient strengths of 200 mT/m and higher can also exist. The higher the gradient strengths are, the steeper the ramps must be when running the gradients up and down. The steeper the ramps are, the more voltage is induced in the components of the MRT system, which, in turn, can lead to corresponding eddy currents.

In another exemplary aspect, the repetition duration of each repetition of the sequence is prolonged, in comparison with a reference repetition duration of a predetermined reference sequence, by the decay duration. If, for example, a reference repetition duration is entirely used up by a predetermined ramp portion and a constant portion that is substantially characterized by the readout procedure, then the repetition duration must be extended by the decay duration if a corresponding decay of the eddy currents is desired. This extension of the repetition duration leads, however, inevitably to the extension of the overall sequence and typically does not represent a desirable option. Under certain circumstances, this extension can, however, actually be wanted.

In an alternative aspect, it is provided that a repetition duration of each repetition of the sequence equals a reference repetition duration of a predetermined reference sequence, and a ramp duration of the ramp portion of each repetition of the sequence is shortened, in comparison with a ramp duration of a reference ramp portion of the predetermined reference sequence, by the decay duration. This means that in the sequence for the ramping up and down of the gradient, a steeper ramp is used than in the reference sequence. This has the advantage that the repetition duration can remain the same so that the decay duration does not prolong the total duration of a sequence.

According to the present disclosure, a method is provided for obtaining image signals by means of an imaging modality of a magnetic resonance system in a k-space. Therein, the image signals in a central region of the k-space are acquired by way of a Cartesian acquisition portion of a sequence and outside the central region by way of a radial acquisition portion of the sequence. In the Cartesian acquisition portion, corresponding image signals are obtained with a method outlined above after a first decay duration. In the radial acquisition portion, corresponding image signals are obtained with the method outlined above after a second decay duration shorter than the first. Specifically, on radial acquisition, the readout procedure typically lasts longer than in the case of a Cartesian acquisition portion. This is due to the fact that in the radial acquisition portion, a radial line of the k-space is acquired, while in the Cartesian acquisition portion, typically only a point in the center of the k-space is acquired. Therefore, during the Cartesian acquisition, a majority or at least a larger part of the repetition duration can be used for the decay.

The above method for obtaining image signals can be improved in that a sum of the second decay duration and a radial readout duration of the readout procedure of the radial acquisition portion of the sequence corresponds to a sum of a Cartesian readout duration of the Cartesian acquisition portion of the sequence and the first decay duration. Thus, the repetition duration can be selected to be the same both for the radial acquisition and also for the Cartesian acquisition, in particular if the same duration of the respective ramp portion is selected for both acquisition types.

The object mentioned above is achieved according to the disclosure by way of a magnetic resonance system with an imaging modality that has a control apparatus. Therein, the control apparatus is configured to control the imaging modality to carry out the aforementioned method.

According to the disclosure, a computer program is also provided which can be loaded directly into a memory store of the control apparatus of the imaging modality of the magnetic resonance system. The computer program has program means in order to carry out the steps of the aforementioned method when the program is executed in the control apparatus of the imaging modality. Herein, the aforementioned method can be carried out by means of a processor, especially by means of a computing unit of the MRT system.

Furthermore, an electronically readable data carrier with electronically readable control information stored thereon can also be provided. The control information comprises at least one computer program of the aforementioned type and is configured such that when the data carrier is used in a control apparatus of an imaging modality of a magnetic resonance system of the aforementioned type, it carries out a method as also set out above.

For application cases or application situations which can arise with the method and which are not explicitly described here, it can be provided that according to the method, an error message and/or a request for input of a user feedback is output and/or a standard setting and/or a predetermined initial state is set.

Independent of the grammatical term usage, individuals with male, female or other gender identities are included within the term.

### BRIEF DESCRIPTION OF THE DRAWINGS

The present disclosure will now be described in greater detail making reference to the accompanying drawings, in which:

FIG. 1 shows a schematic view of a magnetic resonance system;

FIG. 2 shows an exemplary aspect for the acquisition of a k-space;

FIG. 3 shows a repetition according to the prior art;

FIG. 4 shows a first exemplary aspect of a repetition with an additional decay duration;

FIG. 5 shows a repetition in a Cartesian acquisition portion according to the prior art; and

FIG. 6 shows an exemplary aspect of a repetition of a Cartesian acquisition portion with a decay duration for eddy currents.

### DETAILED DESCRIPTION

The exemplary aspects set out in greater detail below represent preferred aspects of the present disclosure.

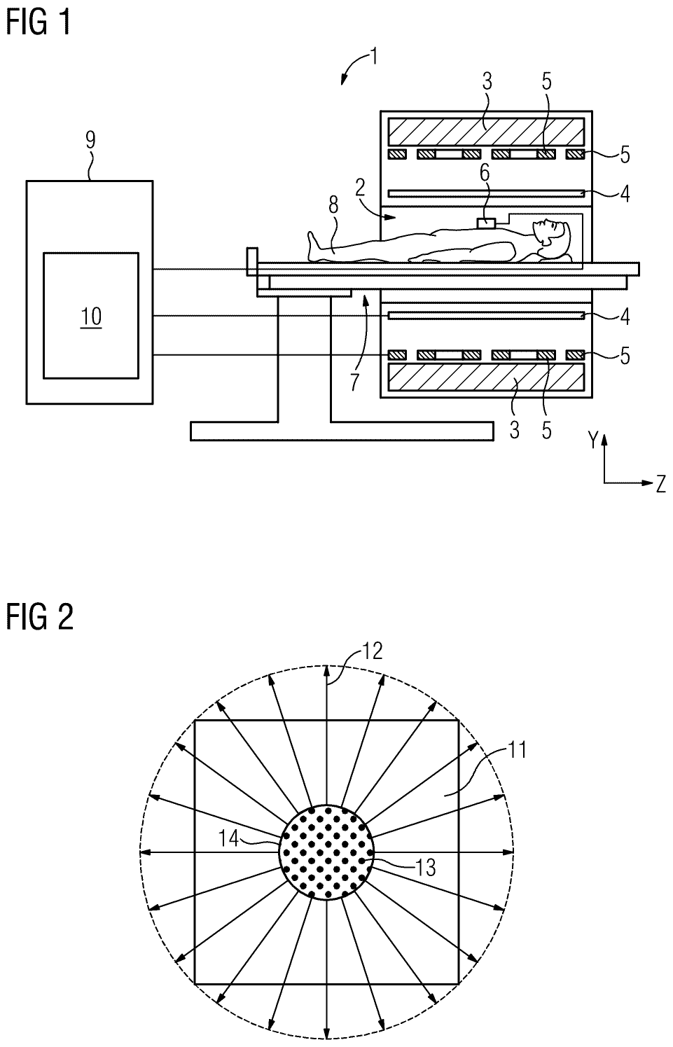

FIG. 1 shows a schematic representation of an exemplary aspect of an MRT system 1 according to the disclosure (also called magnetic resonance system).

The MRT system 1 comprises a magnet unit with a field magnet 3 which generates a static magnetic field for orienting nuclear spins of an object 8, for example a patient, in an imaging region. The imaging region is characterized by an extremely homogeneous static magnetic field, wherein the homogeneity relates, in particular, to the magnetic field strength and/or its amplitude. The imaging region is situated in a patient tunnel 2 which extends in a longitudinal direction Z through the magnet unit. The field magnet 3 can be, for example, a superconducting magnet which can generate magnetic fields with a magnetic flux density of up to 3 T or more. For lower field strengths, however, permanent magnets or electromagnets with normally-conducting coils can also be used. A patient table 7 can be capable of movement within the patient tunnel 2.

Furthermore, the magnet unit comprises a gradient coil arrangement 5 with a plurality of gradient coils which serve to overlay gradient fields, that is, position-dependent magnetic fields in the three spatial directions for spatial differentiation of the scanned image regions in the imaging region, onto the static magnetic gradient field. The gradient coils of the gradient coil arrangement 5 can be configured, for example, as coils of normally-conducting wires which can generate, for example, fields or field gradients orthogonally to one another in the imaging region.

The magnet unit comprises a transmitting coil arrangement which can comprise, for example, a body coil 4 (also referred to as a whole body coil) as the transmitting antenna which is configured to radiate a high frequency signal and/or an excitation signal into the imaging region. The body coil 4 can therefore be understood to be an HF transmitting coil arrangement of the MRT system 1 or as part of the HF transmitting coil arrangement. The body coil 4 can also be used in some aspects to receive resonant MR signals which are emitted by the object 8. In this case, the body coil 4 can also be considered to be part of a signal acquisition apparatus of the MRT system 1. Optionally, the signal acquisition apparatus comprises a local coil 6 which can be arranged in the immediate vicinity of the object 8, for example, on the object 8 or in the patient table 7. The local coil 6 can serve, alternatively or in addition to the body coil 4, as a receiving coil and/or a receiving antenna.

The MRT system 1 also comprises a control and computing system 9. The control and computing system 9 can comprise a transmitting-receiving control unit 10 which is connected to the body coil 4, the gradient coil arrangement 5 and/or the local coil 6. Dependent upon the acquired MR signals, the transmitting-receiving control unit 10 which can comprise an analogue-to-digital converter (ADC), can generate corresponding MR data, in particular in the k-space. The transmitting-receiving control unit 10 is possibly also connected to the body coil 4 and controls it to generate HF pulses such as excitation pulses and/or refocusing pulses. Furthermore, the transmitting-receiving control unit 10 of the control and computing system 9 can also be connected to the gradient coil arrangement 5 and control it in order to switch slice selection gradients, gradients for the frequency and/or phase encoding and/or readout gradients.

FIG. 2 shows a (here, two-dimensional) k-space 11, which is sampled, by way of example, with a PETRA sequence. The sequence diagram shows radial acquisition portions 12 and Cartesian acquisition portions 13. In a radial acquisition portion 12, a radial line outside a k-space center 14 is sampled. The radial acquisition portions 12 are preferably equally distributed in all directions.

Within the k-space center 14, the k-space 11 is sampled point by point in a Cartesian acquisition portion with single points 13. The schematic drawing in FIG. 2 can also represent a slice through the center of a 3D k-space.

The starting point of the optimization according to the disclosure is the need to reduce and/or hinder the influence of eddy currents with short time constants, in particular, in a PETRA sequence. The solution approach is based, for this purpose, on an optimization of the time sequence within a repetition of the respective sequence. In particular, in a repetition the imaging and/or the readout procedure is to be begun only when eddy currents have decayed sufficiently after the ramping of the gradients in a decay time.

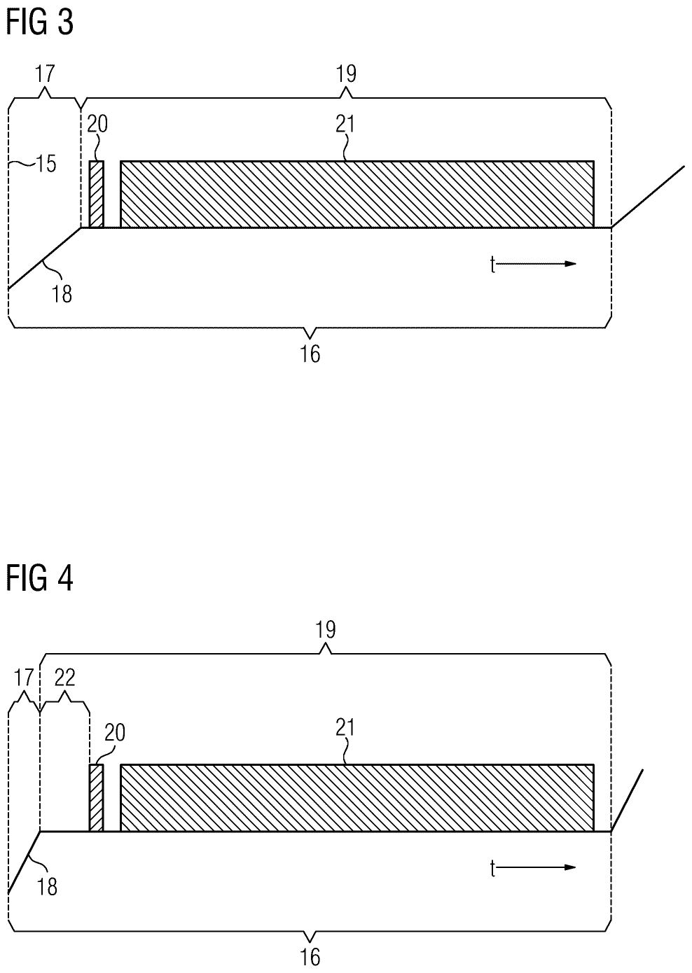

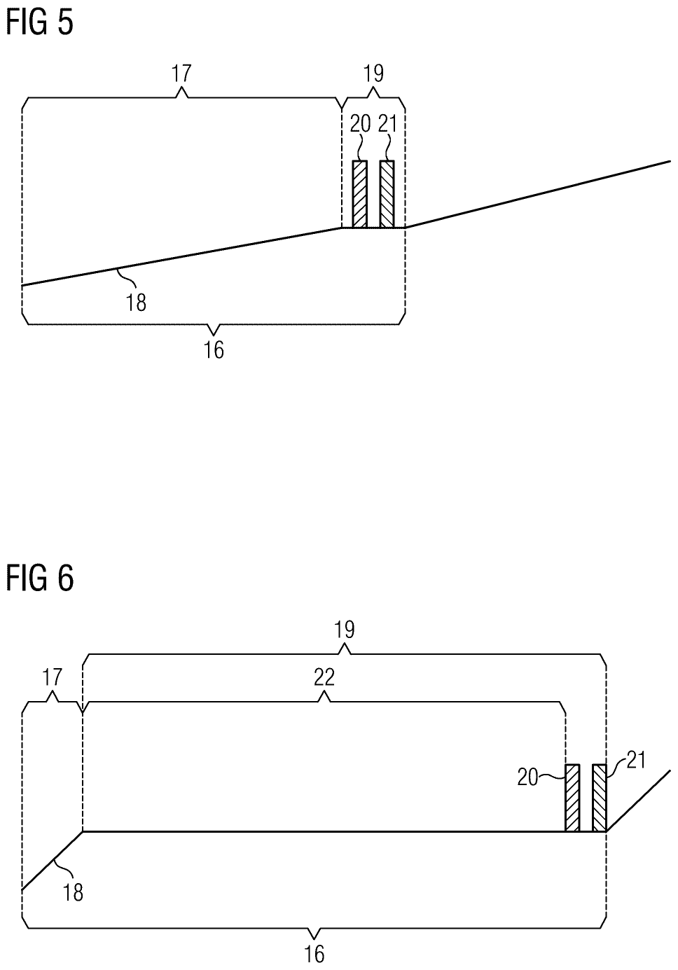

In general, eddy currents are induced in conductive components of the MRT system during the ramping (running up and down of the gradients). In the PETRA sequence named by way of example below, the gradients are ramped, at the beginning 15 of a repetition 16 shown over time t, to the required gradient strength, which is symbolized in FIG. 3 with a ramp portion 17 of a gradient amplitude 18. A constant portion 19 directly adjoins the ramp portion 17. In the constant portion 19, the gradient amplitude 18 of the respective gradient is constant. Typically, an excitation pulse 20 (also called HF pulse) takes place directly following the end of the ramp, i.e., at the start of the constant portion 19. A more or less long readout procedure 21 follows the excitation pulse 20. In the context of the radial acquisition, the readout procedure 21 includes the majority of the repetition 16. In the Cartesian acquisition, however, the readout procedure is relatively short (see FIGS. 5 and 6).

In systems with strong gradient amplitudes, if eddy currents occur during the ramping, they have often not yet decayed at the beginning of the excitation pulse 20 and/or, depending upon the time constant (herein also referred to as the decay duration), into the readout procedure 21, and lead to errors in the encoding and thus unavoidably to image artifacts. For the purpose of the disclosure, it is therefore proposed to provide a sufficiently long decay duration 22 at a constant gradient amplitude 18 during which the eddy currents can decay.

For this purpose, in principle, two approaches are possible. Firstly, an extension of the repetition time and/or of the repetition 16 can be undertaken. Thereby, after the ramp portion 17, a sufficiently long flat-top time (decay duration 22) would ensue before the excitation pulse 20. However, this approach brings with it the disadvantage that the repetition 16, and thus the whole sequence, takes longer.

A second approach provides an increase in the so-called “slew rate”, or a shortening of the ramp time of the ramp portion 17. The result of this, given the same repetition duration, is, therefore, a sufficiently long decay duration before the start of the excitation pulse 20, as FIG. 4 illustrates. This approach can be realized relatively well above all because in sequences such as the PETRA sequence, relatively long ramps are mostly used in order to be able to scan as quietly as possible or silently. Nevertheless, this approach can have the disadvantage that due to the steeper ramps, stronger eddy currents arise, although they are possibly further decayed. For this purpose, the optimization algorithm mentioned below can be utilized.

According to a further aspect of the disclosure, use is to be made of the fact that the PETRA sequence consists of a radial acquisition portion and/or imaging part in which a radial half-spoke is acquired (see FIG. 4), and a Cartesian acquisition portion and/or imaging part in which, per repetition, only a single Cartesian point 13 is acquired in the k-space center 14. Especially the Cartesian part of the sequence can be particularly prone to eddy currents since the contrast and SNR (signal-to-noise ratio) information of the image are contained in the k-space center 14.

Typically, according to FIG. 5, in the Cartesian acquisition portion, particularly long ramps or ramp portions 17 are used in order to make use of the time that remains during the whole duration of the repetition 16 due to the very short readout procedure 21 (as compared with the radial acquisition portion).

For the purpose of the disclosure, in order to obtain a sufficiently long flat-top time for the decay of eddy currents, shorter ramp portions 17 are again used, as FIG. 6 shows. This leads to a long flat-top time or a long constant portion 19 of the gradient amplitude 18. Only shortly before the end of the long constant portion 19 does the excitation pulse 20 and the subsequent readout procedure 21 take place. By this means, there results a long decay duration, which can represent the majority of the duration of a repetition 16. This means that the decay duration 22 can be longer than half the repetition duration. The decay duration is, therefore, not a delay determined by the system but rather is a deliberately inserted wait time during which the system possibly “does nothing.”

If relevant, for the calibration of an MRT system, an algorithm can be used that is able to establish the eddy currents and the length for an artifact-free and/or artifact-limited decay duration. For this purpose, for example, an artifact threshold can be specified which is undershot only given a sufficient decay duration. Dependent upon the result of this calculation, the algorithm can preferably determine optimized gradient and sequence progressions. Under some circumstances, it can also determine whether it is sufficient to optimize only in the Cartesian portion, to use a shorter ramp time also in the radial acquisition portion or to use an extended repetition duration.

In an advantageous manner, by means of the method set out above, the influence of eddy currents, for example, on the PETRA sequence when very high gradient strengths are used, can be limited or prevented. In this way, the advantages (faster readout, fewer readout losses) of systems with very high gradient strengths can advantageously be used for PETRA imaging. The method can comprise, in particular, an advantageous optimization of the sequence progression and the insertion of a decay duration following the ramping of the gradients and before the application of the excitation pulse. The optimization of the sequence progression can be distinguished in that especially in the Cartesian acquisition portion of the sequence, but also in the radial acquisition portion, shorter ramp times can be used, so that with the same repetition duration, space is provided for the decay duration. Alternatively, a non-preferred extension of the repetition times for the decaying of the eddy currents is provided. Particularly advantageously, the aforementioned algorithm for determining the necessary decay duration can be used in order, for example, to automatically take account of system characteristics such as time constants and the gradient amplitudes that are used.

1. A method for operating an imaging modality of a magnetic resonance system by obtaining image signals in a large number of repetitions of an MR sequence, wherein in one of the repetitions, the method comprises:
altering a strength of a gradient field in a ramp portion;
keeping constant the strength of the gradient field in a constant portion adjoining the ramp portion;
carrying out an HF (high frequency) pulse in the constant portion; and
at a beginning of the constant portion, waiting a specifiable decay duration until the HF pulse is carried out.

2. The method as claimed in claim 1, wherein the decay duration is determined automatically by an algorithm based on parameters of the imaging modality.

3. The method as claimed in claim 1, wherein the decay duration is in a range from 1 μs to 5 ms.

4. The method as claimed in claim 1, wherein the decay duration is in a range from 10 μs to 2 ms.

5. The method as claimed in claim 1, wherein the constant portion of the repetition is configured temporally longer than the ramp portion.

6. The method as claimed in claim 1, wherein the strength of the gradient field is at least occasionally above 10 mT/m.

7. The method as claimed in claim 1, wherein the strength of the gradient field is at least occasionally above 20 mT/m.

8. The method as claimed in claim 1, wherein a repetition duration of each repetition of the sequence is prolonged, in comparison with a reference repetition duration of a predetermined reference sequence, by the decay duration.

9. The method as claimed in claim 1, wherein a repetition duration of each repetition of the sequence equals a reference repetition duration of a predetermined reference sequence, and a ramp duration of the ramp portion of each repetition of the sequence is shortened, in comparison with a ramp duration of a reference ramp portion of the predetermined reference sequence, by the decay duration.

10. The method as claimed in claim 1, wherein following the HF pulse, a readout procedure takes place.

11. A method for obtaining image signals using an imaging modality of a magnetic resonance system in a k-space, wherein the image signals in a central region of the k-space are acquired by way of a Cartesian acquisition portion of a sequence and outside the central region by way of a radial acquisition portion of the sequence, and wherein in the Cartesian acquisition portion, corresponding image signals are obtained with a method as claimed in claim 10 following a first decay duration and, in the radial acquisition portion, corresponding image signals are obtained with a method as claimed in claim 10 after a second decay duration which is shorter than the first.

12. The method as claimed in claim 11, wherein a sum of the second decay duration and of a radial readout duration of the readout procedure of the radial acquisition portion of the sequence corresponds to a sum of a Cartesian readout duration of the Cartesian acquisition portion of the sequence and of the first decay duration.

13. A magnetic resonance system with an imaging modality, which has a control apparatus that is configured to control the imaging modality to carry out a method as claimed in claim 1.

14. A non-transitory computer-readable medium having stored thereon a computer program which, when executed in a control apparatus of an imaging modality of a magnetic resonance system, carries out the method as claimed in claim 1.
